(19) United States
(12) Patent Application Publication
(10) Pub. No.: US 2016/0314962 A1
(43) Pub. Date: Oct. 27, 2016

(54) CYCLIC ORGANOAMINOSILANE PRECURSORS FOR FORMING SILICON-CONTAINING FILMS AND METHODS OF USING THE SAME

(71) Applicant: American Air Liquide, Inc., Fremont, CA (US)

(72) Inventors: Katsuko HIGASHINO, Newark, DE (US); Glenn KUCHENBEISER, Newark, DE (US); Christian DUSSARRAT, Tokyo (JP)

(21) Appl. No.: 15/199,330

(22) Filed: Jun. 30, 2016

(51) Int. Cl. H01L 21/02

(52) U.S. Cl. CPC H01L 21/02211; H01L 21/02274; H01L 21/0228; H01L 21/02271; H01L 21/02167; H01L 21/0217; H01L 21/0214

(57) ABSTRACT

Disclosed are methods for forming a silicon-containing layer on a substrate, the method comprising the steps of introducing into a reactor containing a substrate a vapor including an Si-containing film forming composition having a cyclic organoaminosilane precursor having the formula:

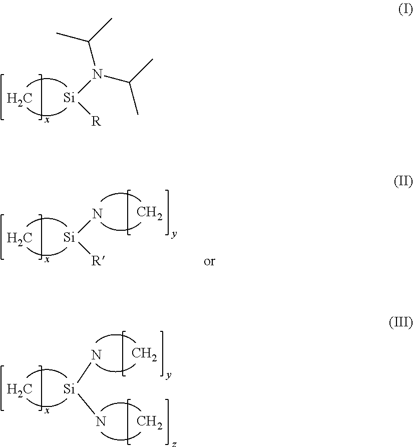

wherein R is NH₂; R′ is H or NH₂; x, y or z=2 to 5; provided that x≠4 in the formula (III), and depositing at least part of the cyclic organoaminosilane precursor onto the substrate to form the silicon-containing layer on the substrate using a vapor deposition process. The cyclic organoaminosilane precursors include bis(pyrrolidino)silacyclopentane and 1-(pyrrolidino)silacyclopentane.

### TECHNICAL FIELD

Disclosed are Si-containing film forming compositions, methods of synthesizing the same, and methods of using the same to deposit silicon-containing films using vapor deposition processes for the manufacture of semiconductor and electronic devices, such as, integrated circuit, interconnects (e.g., BEOL, TSV, etc.), dielectrics, passivation coatings, barrier coatings, spacers, interconnects, liners and/or stressors, memories, MEMS, emerging devices (e.g., power devices, image sensors, etc.), photovoltaic, LCD-TFT, displays, lighting LEDs, refractory materials, or aeronautics. The disclosed Si-containing film forming compositions comprise a cyclic organoaminosilane precursor having the formula:

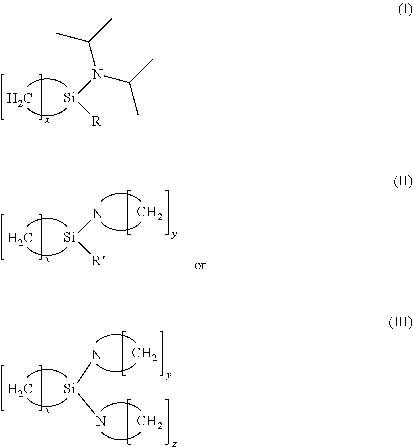

wherein R is NH₂; R′ is H or NH₂; x, y or z=2 to 5; provided that x≠4 in the formula (III).

### BACKGROUND

Si-containing thin films (e.g., SiO₂, SiN, SiCN, SiCOH, MSiOₓ, wherein M is Hf, Zr, Ti, Nb, Ta, or Ge and x is greater than zero) may be used, for example, as dielectric materials having electrical properties which may be insulating, and also used as conducting films, such as metal silicides or metal silicon nitrides, in semiconductor industry, such as, transistor engineering, interconnects (e.g., BEOL, TSV, etc.), memories, MEMS, emerging devices (e.g., power devices, image sensors, etc.), photovoltaics, or aeronautics.

Due to the strict requirements imposed by downscaling of electrical device architectures towards the nanoscale, especially below 28 nm node, increasingly fine-tuned molecular precursors are required which meet the requirements of volatility for atomic layer deposition (ALD) and chemical vapor deposition (CVD) processes, lower process temperatures, reactivity with various oxidants and low film contamination, in addition to high deposition rates, conformality and consistency of films produced.

Organoaminosilanes have been disclosed as precursors for the deposition of silicon containing films such as silicon-oxide or silicon-nitride or silicon carbonitride films. For example, U.S. Pat. No. 9,233,990 to Xiao et al. discloses organoaminosilanes, such as without limitation di-iso-propylaminosilane, are precursors for the deposition of silicon containing films such as silicon-oxide and silicon-nitride films. The disclosed compounds include 1-(N,N-di-iso-propylamino)-silacyclopentane.

Another example is U.S. Pat. No. 9,117,664 to Zhou et al. teaches bis(pyrrolidino)silacyclobutane, as CVD precursor for films like silicon nitride, silicon carbonitride, silicon dioxide or carbon doped silicon dioxide.

Despite the wide range of choices available for the deposition of Si-containing films, additional precursors are continuously sought to provide device engineers the ability to tune manufacturing process requirements and achieve films with desirable electrical and physical properties.

### SUMMARY

Disclosed are Si-containing film forming compositions comprising a cyclic organoaminosilane precursor having the formula:

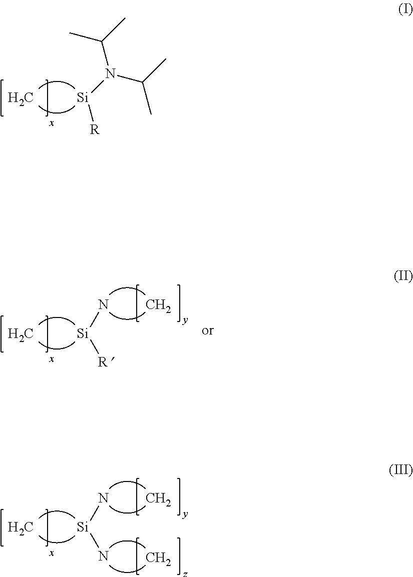

wherein R is NH₂; R′ is H or NH₂; x, y or z=2 to 5; provided that x≠4 in the formula (III).

The disclosed Si-containing film forming compositions may have one or more of the following aspects:
the cyclic organoaminosilane precursor being silacycloalkane or silacycloalkane-containg substituted structure;
the cyclic organoaminosilane precursor containing no terminal methyl groups on silicon;
the cyclic organoaminosilane precursor being selected from substitutions of heterocyclic amines comprising of unsaturated nitrogen heterocycles, such as, pyrrole, imidazole and 3-pyrroline;
the cyclic organoaminosilane precursor being (pyrrolidinyl)silacyclopentanes which may contain either one or two pyrrolidinyl groups at Si in addition to 5 member ring containing methylene —CH₂— groups;
the cyclic organoaminosilane precursor being 1-(diisopropylamino)-1-amino-silacyclopentane;
the cyclic organoaminosilane precursor being 1-(pyrrolidino)silacyclobutane;
the cyclic organoaminosilane precursor being 1-(pyrrolidino)silacyclopentane;
the cyclic organoaminosilane precursor being 1-(pyrrolidino)silacyclohexane;
the cyclic organoaminosilane precursor being 1-(piperidino)silacyclobutane;
the cyclic organoaminosilane precursor being 1-(piperidino)silacyclopentane;
the cyclic organoaminosilane precursor being 1-(piperidino)silacyclohexane;
the cyclic organoaminosilane precursor being 1-(pyrrolidino)-1-amino-silacyclobutane;
the cyclic organoaminosilane precursor being 1-(pyrrolidino)-1-amino-silacyclopentane;
the cyclic organoaminosilane precursor being 1-(pyrrolidino)-1-amino-silacyclohexane;
the cyclic organoaminosilane precursor being 1-(piperidino)-1-amino-silacyclobutane;
the cyclic organoaminosilane precursor being 1-(piperidino)-1-amino-silacyclopentane;
the cyclic organoaminosilane precursor being 1-(piperidino)-1-amino-silacyclohexane;
the cyclic organoaminosilane precursor being bis(pyrrolidino)silacyclopentane;
the cyclic organoaminosilane precursor being bis(pyrrolidino)silacyclohexane;
the cyclic organoaminosilane precursor being bis(piperidino)silacyclobutane;
the cyclic organoaminosilane precursor being bis(piperidino)silacyclopentane;
the cyclic organoaminosilane precursor being bis(piperidino)silacyclohexane,
the Si-containing film forming composition comprising between approximately 95% w/w and approximately 100% w/w of the compound;
the Si-containing film forming composition composition comprising between approximately 5% w/w and approximately 50% w/w of the compound;
the Si-containing film forming composition comprising between approximately 0 ppbw and approximately 100 ppbw Al;
the Si-containing film forming composition comprising between approximately 0 ppbw and approximately 100 ppbw As;
the Si-containing film forming composition comprising between approximately 0 ppbw and approximately 100 ppbw Ba;
the Si-containing film forming composition comprising between approximately 0 ppbw and approximately 100 ppbw Be;
the Si-containing film forming composition comprising between approximately 0 ppbw and approximately 100 ppbw Bi;
the Si-containing film forming composition comprising between approximately 0 ppbw and approximately 100 ppbw Cd;
the Si-containing film forming composition comprising between approximately 0 ppbw and approximately 100 ppbw Ca;
the Si-containing film forming composition comprising between approximately 0 ppbw and approximately 100 ppbw Cr;
the Si-containing film forming composition comprising between approximately 0 ppbw and approximately 100 ppbw Co;
the Si-containing film forming composition comprising between approximately 0 ppbw and approximately 100 ppbw Cu;
the Si-containing film forming composition comprising between approximately 0 ppbw and approximately 100 ppbw Ga;
the Si-containing film forming composition comprising between approximately 0 ppbw and approximately 100 ppbw Ge;
the Si-containing film forming composition comprising between approximately 0 ppbw and approximately 100 ppbw Hf;
the Si-containing film forming composition comprising between approximately 0 ppbw and approximately 100 ppbw Zr;
the Si-containing film forming composition comprising between approximately 0 ppbw and approximately 100 ppbw In;
the Si-containing film forming composition comprising between approximately 0 ppbw and approximately 100 ppbw Fe;
the Si-containing film forming composition comprising between approximately 0 ppbw and approximately 100 ppbw Pb;
the Si-containing film forming composition comprising between approximately 0 ppbw and approximately 100 ppbw Li;
the Si-containing film forming composition comprising between approximately 0 ppbw and approximately 100 ppbw Mg;
the Si-containing film forming composition comprising between approximately 0 ppbw and approximately 100 ppbw Mn;
the Si-containing film forming composition comprising between approximately 0 ppbw and approximately 100 ppbw W;
the Si-containing film forming composition comprising between approximately 0 ppbw and approximately 100 ppbw Ni;
the Si-containing film forming composition comprising between approximately 0 ppbw and approximately 100 ppbw K;
the Si-containing film forming composition comprising between approximately 0 ppbw and approximately 100 ppbw Na;
the Si-containing film forming composition comprising between approximately 0 ppbw and approximately 100 ppbw Sr;
the Si-containing film forming composition comprising between approximately 0 ppbw and approximately 100 ppbw Th;
the Si-containing film forming composition comprising between approximately 0 ppbw and approximately 100 ppbw Sn;
the Si-containing film forming composition comprising between approximately 0 ppbw and approximately 100 ppbw Ti;
the Si-containing film forming composition comprising between approximately 0 ppbw and approximately 100 ppbw U;
the Si-containing film forming composition comprising between approximately 0 ppbw and approximately 100 ppbw V;
the Si-containing film forming composition comprising between approximately 0 ppbw and approximately 100 ppbw Zn;
the Si-containing film forming composition comprising between approximately 0 ppmw and approximately 100 ppmw F;
the Si-containing film forming composition comprising between approximately 0 ppmw and approximately 100 ppmw Cl;
the Si-containing film forming composition comprising between approximately 0 ppmw and approximately 100 ppmw Br; and
the Si-containing film forming composition comprising between approximately 0 ppmw and approximately 100 ppmw I.

Also disclosed are methods of depositing a Si-containing layer on a substrate. A cyclic organoaminosilane precursor disclosed above is introduced into a reactor having a substrate disposed therein. At least part of the cyclic organoaminosilane precursor is deposited onto the substrate to form the Si-containing layer using a vapor deposition method. The disclosed methods may have one or more of the following aspects:
introducing into the reactor a vapor comprising a second precursor;
an element of the second precursor being selected from the group consisting of group 2, group 13, group 14, transition metal, lanthanides, and combinations thereof;
an element of the second precursor being selected from Si, Mn, Pt, Ti, Ta, Bi, Hf, Zr, Pb, Nb, Mg, Al, Sr, Y, Ba, Ca, Ni, Co, Lanthanide and combinations thereof;
introducing a reactant into the reactor;
The reactant being selected from the group consisting of N₂, H₂, NH₃, O₂, O₃, H₂O, monomethyl-hydrazine, H₂O₂, SiH₄, trisilylamine (TSA), monochlorosilane (MCS), dichlorosilane (DCS), trichlorosilane (TCS), monomethylsilane (MMS), SiCl₄, bis(tert-butylamino)silane (BTBAS), SiH₂(NEt₂)₂, SiH₃(NiPr₂), hexachlorodisilane (HCDS), pentachlorodisilane (PCDS), trimethylamine or any combination thereof with or without plasma;
the reactant being selected from the group consisting of O₂, O₃, H₂O, H₂O₂, NO, NO₂, a carboxylic acid, radicals thereof, and combinations thereof;
the reactant being plasma treated oxygen;
the reactant being ozone;
the reactant being selected from the group consisting of H₂, NH₃, (SiH₃)₃N, hydridosilanes (such as SiH₄, Si₂H₆, Si₃H₈, Si₄H₁₀, Si₅H₁₀, Si₆H₁₂), chlorosilanes and chloropolysilanes (such as SiHCl₃, SiH₂Cl₂, SiH₃Cl, Si₂Cl₆, Si₂HCl₅, Si₃Cl₈), alkysilanes (such as Me₂SiH₂, Et₂SiH₂, MeSiH₃, EtSiH₃), hydrazines (such as N₂H₄, MeHNNH₂, MeHNNHMe), organic amines (such as NMeH₂, NEtH₂, NMe₂H, NEt₂H, NMe₃, NEt₃, (SiMe₃)₂NH), pyrazoline, pyridine, B-containing molecules (such as B₂H₆, 9-borabicylo[3,3,1]none, trimethylboron, triethylboron, borazine), alkyl metals (such as trimethylaluminum, triethylaluminum, dimethylzinc, diethylzinc), radical species thereof, and mixtures thereof;
the reactant being selected from the group consisting of H₂, NH₃, SiH₄, Si₂H₆, Si₃H₈, SiH₂Me₂, SiH₂Et₂, N(SiH₃)₃, hydrogen radicals thereof, and mixtures thereof;
the reactant being HCDS or PCDS or diiodosilane;
the vapor deposition method being a CVD process;
the vapor deposition method being an ALD process;
the vapor deposition method being a spatial ALD process;
the vapor deposition method being a PECVD process;
the vapor deposition method being a PEALD process;
the silicon-containing layer being Si;
the silicon-containing layer being SiO₂;
the silicon-containing layer being SiN;
the silicon-containing layer being SiC;
the silicon-containing layer being SiON;
the silicon-containing layer being SiCN; and
the silicon-containing layer being SiCOH.

### NOTATION AND NOMENCLATURE

The following detailed description and claims utilize a number of abbreviations, symbols, and terms, which are generally well known in the art. While definitions are typically provided with the first instance of each acronym, for convenience, Table 1 provides a list of the abbreviations, symbols, and terms used along with their respective definitions.

TABLE 1

| | |
|---|---|
| a or an | One or more than one |
| Approximately | ±10% of the value stated |
| or about | |
| MEMS | Micro-Electro-Mechanical Systems |
| BEOL | Back end of line |
| TSV | Through silicon via |
| CVD | chemical vapor deposition |
| LPCVD | low pressure chemical vapor deposition |
| PCVD | pulsed chemical vapor deposition |
| SACVD | sub-atmospheric chemical vapor deposition |
| PECVD | plasma enhanced chemical vapor deposition |
| APCVD | atmospheric pressure chemical vapor deposition |
| HWCVD | hot-wire chemical vapor deposition |
| Flowable PECVD | flowable plasma enhanced chemical vapor deposition |
| MOCVD | metal organic chemical vapor deposition |
| ALD | atomic layer deposition |
| spatial ALD | spatial atomic layer deposition |
| HWALD | hot-wire atomic layer deposition |
| PEALD | plasma enhanced atomic layer deposition |
| DSSD | dual silicone source deposition |
| RFO | restrictive flow orifice |
| LCD-TFT | liquid-crystal display thin-film transistor |
| MIM | metal-insulator-metal |
| DRAM | dynamic random-access memory |
| FeRam | ferroelectric random-access memory |
| HCDS | hexachlorodisilane |
| PCDS | pentachlorodisilane |
| TSA | trisilylamine |
| MCS | monochlorosilane |
| DCS | dichlorosilane |
| TCS | trichlorosilane |
| MMS | monomethylsilane |
| BTBAS | bis(tert-butylamino)silane |
| sccm | standard cubic centimeters per minute |
| TGA | thermogravimetric analysis |
| DSC | differential scanning calorimetry |
| RI | refractive index |
| heterocycle | cyclic compounds that has atoms of at least two |
| | different elements as members of its ring |

The standard abbreviations of the elements from the periodic table of elements are used herein. It should be understood that elements may be referred to by these abbreviations (e.g., Si refers to silicon, N refers to nitrogen, O refers to oxygen, C refers to carbon, etc.).

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a side view of one embodiment of the Si-containing film forming composition delivery device 1;

FIG. 2 is a side view of a second embodiment of the Si-containing film forming composition delivery device 1;

FIG. 3 is a thermogravimetric analysis (TGA) graph demonstrating the percentage of weight loss of bis(pyrrolidino)silacyclopentane with increasing temperature;

FIG. 4 is a graph of the differential scanning calorimetry (DSC) measurement for bis(pyrrolidino)silacyclopentane;

FIG. 5 is a TGA graph demonstrating the percentage of weight loss of 1-(pyrrolidino)silacyclopentane with increasing temperature;

FIG. 6 is a graph of a DSC measurement for 1-(pyrrolidino)silacyclopentane;

FIG. 7 is a graph of the k value and RI value as a function of the post deposition aging time in days for the film deposited using bis(pyrrolidino)silacyclopentane precursor by PECVD at 5 torr and 8 torr, respectively;

FIG. 8 is a graph of XPS analysis data for the film deposited with bis(pyrrolidino)silacyclopentane by PECVD without UV curing;

FIG. 9 is a graph of XPS analysis data for the film deposited with bis(pyrrolidino)silacyclopentane by PECVD with UV curing;

FIG. 10 is a graph of k value and RI value as a function of the post deposition storage time in days for the film deposited using diisopropylaminosilacylopentane by PECVD at 8 torr;

FIG. 11 is a graph of XPS analysis data for the film deposited using diisopropylaminosilacylopentane by PECVD without UV curing; and

FIG. 12 is a graph of XPS analysis data for the film deposited using diisopropylaminosilacylopentane by PECVD with UV curing.

### DESCRIPTION OF PREFERRED EMBODIMENTS

Disclosed are Si-containing film forming compositions comprising cyclic organoaminosilane precursors having the following formula:

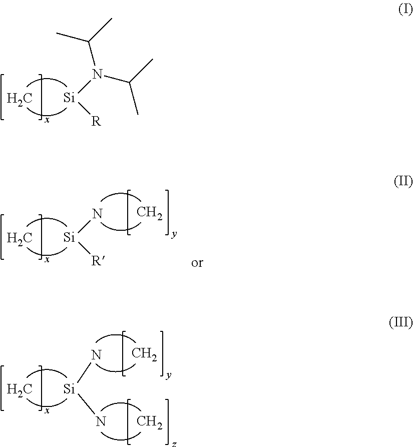

wherein R is NH₂; R′ is H or NH₂; x, y or z=2 to 5; provided that x≠4 in the formula (III).

The main structure of the disclosed cyclic organoaminosilane precursors may be silacycloalkane or silacycloalkane-containg substituted structure, but is not limited to.

The disclosed cyclic organoaminosilane precursors contain no terminal methyl groups on silicon.

The disclosed cyclic organoaminosilane precursors may be selected from substitutions of heterocyclic amines comprising unsaturated nitrogen heterocycles, such as, pyrrole, imidazole and 3-pyrroline.

The disclosed cyclic organoaminosilane precursors may be (pyrrolidinyl)silacyclopentanes which may contain either one or two pyrrolidinyl groups at Si in addition to 5 member ring containing methylene —CH₂— groups.

The disclosed cyclic organoaminosilane precursors may be selected from the group consisting of 1-(diisopropylamino)-1-amino-silacyclopentane, 1-(pyrrolidino)silacyclobutane, 1-(pyrrolidino)silacyclopentane, 1-(pyrrolidino)silacyclohexane, 1-(piperidino)silacyclobutane, 1-(piperidino)silacyclopentane, 1-(piperidino)silacyclohexane, 1-(pyrrolidino)-1-amino-silacyclobutane, 1-(pyrrolidino)-1-amino-silacyclopentane, 1-(pyrrolidino)-1-amino-silacyclohexane, 1-(piperidino)-1-amino-silacyclobutane, 1-(piperidino)-1-amino-silacyclopentane, 1-(piperidino)-1-amino-silacyclohexane, bis(pyrrolidino)silacyclopentane, bis(pyrrolidino)silacyclohexane, bis(piperidino)silacyclobutane, bis(piperidino)silacyclopentane, bis(piperidino)silacyclohexane, and mixtures thereof.

The disclosed cyclic organoaminosilane precursor may be 1-(pyrrolidino)silacyclopentane.

The disclosed cyclic organoaminosilane precursor may be bis(pyrrolidino)silacyclopentane.

Preferably, the disclosed Si-containing film forming compositions have suitable properties for vapor depositions methods, such as vapor pressure ranging from approximately 0.1 Torr at 23° C. to approximately 1,000 Torr at 23° C., a melting point below 20° C. (preferably being in liquid form at room temperature) and more preferably below −20° C. to prevent freeze/thaw issues, and exhibiting 0% v/v to 1% v/v decomposition per week at the desired process temperature.

The advantages of the disclosed cyclic organoaminosilane precursors may (i) suppress the k value drift with aging by eliminating Si—H and (ii) provide low k value with high hydrocarbon content in the film.

The disclosed Si-containing film forming compositions may be suitable for the deposition of Si-containing films, such as, SiCN, SiN, SiC, SiCOH or SiON films, by various plasma enhanced ALD or CVD processes, such as, PEALD, PECVD, or other deposition methods, such as, ALD, CVD, flowable ALD/CVD, DSSD, selective ALD, and may have the following advantages:
liquid at room temperature or having a melting point lower than 50° C.;
thermally stable to enable proper distribution (gas phase or direct liquid injection) without particles generation;
suitable reactivity with the substrate to permit a wide self-limited ALD window, allowing deposition of a variety of Si-films, including ternary or quaternary materials, by using one or a combination of reactants (selected from the group comprising of H₂, NH₃, O₂, H₂O, O₃, SiH₄, Si₂H₆, Si₃H₈, SiH(NMe₂)₃ (TriDMAS or TDMAS), SiH₂(NMe₂)₂ (BDMAS), SiH₂(N(Et)₂)₂ (BDEAS), SiH(N(Et)₂)₃(TDEAS), SiH(NEtMe)₃ (TEMAS), (SiH₃)₃N, (SiH₃)₂O, (GeH₃)₂, Bu₄Ge, GeMe₄, GeEt₄, Ge(allyl), (Ge(NMe₂)₄, Ge(N(SiMe₃)₂)₄, GeCl₂-dioxane, GeBr₂, GeCl₄, Ge(OMe)₄, Ge(OEt)₄, Sn(O^{t}Bu)₄, SnI₄, SnMe₄, Sn(AcAc)₂, Sn(NMe₂)₄, Sn(NEt₂)₄, Sn(N(SiMe₃)₂)₂, an aluminum-containing precursor such as trimethyl aluminum (TMA), (tert-butylimido)tris(diethylamido) tantalum (TBTDET), tantalum tetraethoxide dimethylaminoethoxide (TAT-DMAE), polyethylene terephthalate (PET), (tert-butylimido)bis(dimethylamino)niobium (TBTDEN), polyethylene naphthalate (PEN), lanthanide-containing precursors such as Ln(tmhd)₃ (lanthanide (2,2,6,6-tetramethyl-3,5-heptanedione)₃)).

The disclosed cyclic organoaminosilane precursors may be synthesized by loading the reaction flask with pyrrolidine (or piperideine) and a 0° C. solution of a silacycloalkane having a substituent ligand corresponding to a resulting cyclic organoaminosilane precursor in a solvent (e.g., hexane or toluene) with vigorous stirring. After the addition is complete, the suspension is warmed to ambient temperature while stirring overnight. The following day, stirring is stopped to allow precipitate to settle and supernatent solution filtered over a medium pore glass frit with a bed of Celite. The precipitate is then extracted with pentane and the extracts combined and filtered with above to yield a colorless solution. Syntheses of some disclosed precursors are shown in the Examples.

To ensure process reliability, the disclosed Si-containing film forming compositions may be purified by continuous or fractional batch distillation prior to use to a purity ranging from approximately 95% w/w to approximately 100% w/w, preferably ranging from approximately 98% w/w to approximately 100% w/w. One of ordinary skill in the art will recognize that the purity may be determined by H NMR or gas or liquid chromatography with mass spectrometry. The Si-containing film forming compositions may contain any of the following impurities: alkylamines, dialkylamines, alkylimines, THF, ether, pentane, cyclohexane, heptanes, toluene, halogenated metal compounds. Preferably, the total quantity of these impurities is below 0.1% w/w. The purified composition may be produced by recrystallization, sublimation, distillation, and/or passing the gas or liquid through a suitable adsorbent, such as 4 Å molecular sieves.

The concentration of each solvent, such as THF, ether, pentane, cyclohexane, heptanes, and/or toluene, in the purified Si-containing film forming compositions may range from approximately 0% w/w to approximately 5% w/w, preferably from approximately 0% w/w to approximately 0.1% w/w. Solvents may be used in the Si-containing film forming composition's synthesis. Separation of the solvents from the composition may be difficult if both have similar boiling points. Cooling the mixture may produce solid precursor in liquid solvent, which may be separated by filtration. Vacuum distillation may also be used, provided the composition is not heated above approximately its decomposition point.

The disclosed Si-containing film forming composition contains less than 5% v/v, preferably less than 1% v/v, more preferably less than 0.1% v/v, and even more preferably less than 0.01% v/v of any of its analogs or other reaction products. This embodiment may provide better process repeatability. This embodiment may be produced by distillation of the Si-containing film forming composition.

Alternatively, the disclosed Si-containing film forming compositions may comprise between approximately 5% w/w to approximately 50% w/w of one compound with the balance of the composition comprising a second compound, particularly when the mixture provides improved process parameters or isolation of the target compound is too difficult or expensive. For example, the disclosed Si-containing film forming compositions may be 40/60% w/w of 1-(pyrrolidino)silacyclopentane and bis(pyrrolidino)silacyclopentane. The mixture may produce a stable, liquid composition suitable for vapor deposition.

The concentration of trace metals and metalloids in the purified Si-containing film forming composition may each range independently from approximately 0 ppbw to approximately 100 ppbw, and more preferably from approximately 0 ppbw to approximately 10 ppbw. These metal or metalloid impurities include, but are not limited to, Aluminum(Al), Arsenic(As), Barium(Ba), Beryllium(Be), Bismuth(Bi), Cadmium(Cd), Calcium(Ca), Chromium(Cr), Cobalt(Co), Copper(Cu), Gallium(Ga), Germanium(Ge), Hafnium(Hf), Zirconium(Zr), Indium(In), Iron(Fe), Lead(Pb), Lithium(Li), Magnesium(Mg), Manganese(Mn), Tungsten(W), Nickel(Ni), Potassium(K), Sodium(Na), Strontium(Sr), Thorium(Th), Tin(Sn), Titanium(Ti), Uranium(U), Vanadium(V) and Zinc(Zn). The concentration of X (where X=Cl, Br, I) in the purified Si-containing film forming composition may range between approximately 0 ppmw and approximately 100 ppmw and more preferably between approximately 0 ppmw to approximately 10 ppmw.

Care should be taken to prevent exposure of the disclosed Si-containing film forming compositions to water as this may result in decomposition of the cyclic organoaminosilane precursors.

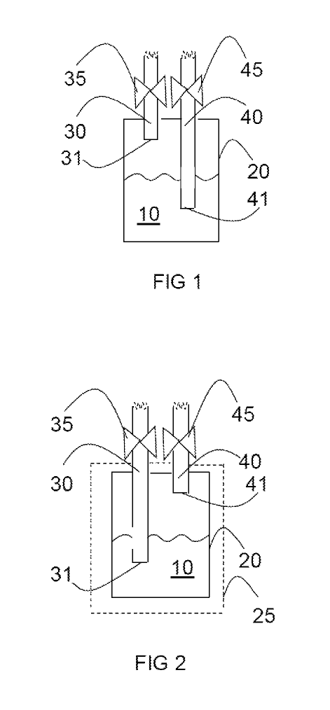

The disclosed Si-containing film forming compositions may be delivered to a semiconductor processing tool by the disclosed Si-containing film forming composition delivery devices. FIGS. 1 and 2 show two embodiments of the disclosed delivery devices 1.

FIG. 1 is a side view of one embodiment of the Si-containing film forming composition delivery device 1. In FIG. 1, the disclosed Si-containing film forming composition 10 are contained within a container 20 having two conduits, an inlet conduit 30 and an outlet conduit 40. One of ordinary skill in the precursor art will recognize that the container 20, inlet conduit 30, and outlet conduit 40 are manufactured to prevent the escape of the gaseous form of the Si-containing film forming composition 10, even at elevated temperature and pressure.

Suitable valves include spring-loaded or tied diaphragm valves. The valve may further comprise a restrictive flow orifice (RFO). The delivery device should be connected to a gas manifold and in an enclosure. The gas manifold should permit the safe evacuation and purging of the piping that may be exposed to air when the delivery device is replaced so that any residual amounts of the pyrophoric material do not react. The enclosure should be equipped with sensors and fire control capability to control the fire in the case of a pyrophoric material release. The gas manifold should also be equipped with isolation valves, vacuum generators, and permit the introduction of a purge gas at a minimum.

The delivery device fluidly connects to other components of the semiconductor processing tool, such as the gas cabinet disclosed above, via valves 35 and 45. Preferably, the delivery device 20, inlet conduit 30, valve 35, outlet conduit 40, and valve 45 are made of 316L EP or 304 stainless steel. However, one of ordinary skill in the art will recognize that other non-reactive materials may also be used in the teachings herein and that any corrosive Si-containing film forming composition 10 may require the use of more corrosion-resistant materials, such as Hastelloy or Inconel.

In FIG. 1, the end 31 of inlet conduit 30 is located above the surface 11 of the Si-containing film forming composition 10, whereas the end 41 of the outlet conduit 40 is located below the surface 11 of the Si-containing film forming composition 10. In this embodiment, the Si-containing film forming composition 10 is preferably in liquid form. An inert gas, including but not limited to nitrogen, argon, helium, and mixtures thereof, may be introduced into the inlet conduit 30. The inert gas pressurizes the delivery device 20 so that the liquid Si-containing film forming composition 10 is forced through the outlet conduit 40 and to components in the semiconductor processing tool (not shown). The semiconductor processing tool may include a vaporizer which transforms the liquid Si-containing film forming composition 10 into a vapor, with or without the use of a carrier gas such as helium, argon, nitrogen or mixtures thereof, in order to deliver the vapor to a chamber where a wafer to be repaired is located and treatment occurs in the vapor phase. Alternatively, the liquid Si-containing film forming composition 10 may be delivered directly to the wafer surface as a jet or aerosol.

FIG. 2 is a side view of a second embodiment of the Si-containing film forming composition delivery device 1. In FIG. 2, the end 31 of inlet conduit 30 is located below the surface 11 of the Si-containing film forming composition 10, whereas the end 41 of the outlet conduit 40 is located above the surface 11 of the Si-containing film forming composition 10. FIG. 2, also includes an optional heating element 25, which may increase the temperature of the Si-containing film forming composition 10. The Si-containing film forming composition 10 may be in solid or liquid form. An inert gas, including but not limited to nitrogen, argon, helium, and mixtures thereof, is introduced into the inlet conduit 30. The inert gas flows through the Si-containing film forming composition 10 and carries a mixture of the inert gas and vaporized Si-containing film forming composition 10 to the outlet conduit 40 and on to the components in the semiconductor processing tool.

Both FIGS. 1 and 2 include valves 35 and 45. One of ordinary skill in the art will recognize that valves 35 and 45 may be placed in an open or closed position to allow flow through conduits 30 and 40, respectively. Either delivery device 1 in FIG. 1 or 2, or a simpler delivery device having a single conduit terminating above the surface of any solid or liquid present, may be used if the Si-containing film forming composition 10 is in vapor form or if sufficient vapor pressure is present above the solid/liquid phase. In this case, the Si-containing film forming composition 10 is delivered in vapor form through the conduit 30 or 40 simply by opening the valve 35 in FIG. 1 or 45 in FIG. 2, respectively. The delivery device 1 may be maintained at a suitable temperature to provide sufficient vapor pressure for the Si-containing film forming composition 10 to be delivered in vapor form, for example by the use of an optional heating element 25.

While FIGS. 1 and 2 disclose two embodiments of the Si-containing film forming composition delivery device 1, one of ordinary skill in the art will recognize that the inlet conduit 30 and outlet conduit 40 may both be located above or below the surface 11 of the Si-containing film forming composition 10 without departing from the disclosure herein. Furthermore, inlet conduit 30 may be a filling port. Finally, one of ordinary skill in the art will recognize that the disclosed Si-containing film forming composition may be delivered to semiconductor processing tools using other delivery devices, such as the ampoules disclosed in WO 2006/059187 to Jurcik et al., without departing from the teachings herein.

Also disclosed are methods of using the disclosed Si-containing film forming compositions for vapor deposition methods. The disclosed methods provide for the use of the Si-containing film forming compositions for deposition of Si-containing films. The disclosed methods may be useful in the manufacture of semiconductor, integrated circuit, interconnects (e.g., BEOL, TSV, etc.), memories, MEMS, emerging devices (e.g., power devices, image sensors, etc.), photovoltaic, LCD-TFT, flat panel type devices, refractory materials, or aeronautics.

The disclosed methods for forming a silicon-containing film, such as, SiCN, SiN, SiC, SiCOH or SiON film, includes: placing an integrated circuit substrate having the metal interconnection in a reactor, delivering into the reactor a vapor of the disclosed Si-containing film forming composition comprising the disclosed cyclic organoaminosilane precursor having the formula:

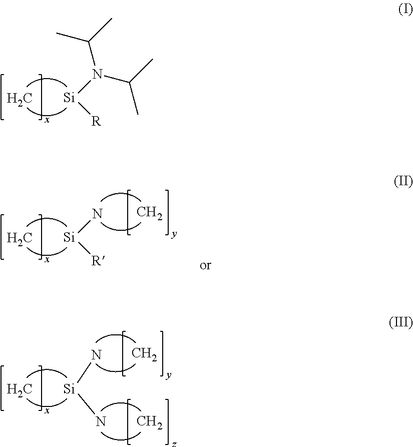

wherein R is NH₂; R′ is H or NH₂; x, y or z=2 to 5; provided that x≠4 in the formula (III), and depositing at least part of the disclosed cyclic organoaminosilane precursor onto the integrated circuit substrate to form the silicon-containing film on the integrated circuit substrate using a vapor deposition process.

The methods may include forming a bimetal-containing layer on a substrate using the vapor deposition process and, more specifically, for deposition of SiMOₓ films wherein x is 4 and M is Ta, Hf, Nb, Mg, Al, Sr, Y, Ba, Ca, As, Sb, Bi, Sn, Pb, Co, lanthanides (such as Er), or combinations thereof. The disclosed methods may be useful in the manufacture of semiconductor, photovoltaic, LCD-TFT, or flat panel type devices. An oxygen source, such as O₃, O₂, H₂O, NO, H₂O₂, acetic acid, formalin, para-formaldehyde, oxygen radicals thereof, and combinations thereof, but preferably O₃ or plasma treated O₂, may also be introduced into the reactor.

The disclosed Si-containing film forming compositions may be used to deposit Si-containing films using any deposition methods known to those of skill in the art. Examples of suitable deposition methods include chemical vapor deposition (CVD) or atomic layer deposition (ALD). Exemplary CVD methods include thermal CVD, pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), radicals incorporated CVD, plasma enhanced CVD (PECVD) including but not limited to flowable PECVD, and combinations thereof. Exemplary ALD methods include thermal ALD, plasma enhanced ALD (PEALD), spatial isolation ALD, hot-wire ALD (HWALD), radicals incorporated ALD, and combinations thereof. Super critical fluid deposition may also be used. The deposition method is preferably ALD, PE-ALD, or spatial ALD in order to provide suitable step coverage and film thickness control. A deposition method may be broadly defined as a way of introducing jointly or sequentially one or multiple gases into a reaction chamber, with or without purge time(s) in between.

The disclosed Si-containing film forming compositions may be used to deposit Si-containing films using PECVD, in which the high frequency (13 MHz) plasma power density may be range from 0.10 to 0.80 W/cm³.

The vapor of the Si-containing film forming composition is generated and then introduced into a reaction chamber containing an integrated circuit substrate having a metal interconnection. The temperature and the pressure in the reaction chamber and the temperature of the integrated circuit substrate are held at conditions suitable for vapor deposition of at least part of the cyclic organoaminosilane precursor onto the substrate. In other words, after introduction of the vaporized composition into the reaction chamber, conditions within the reaction chamber are adjusted such that at least part of the cyclic organoaminosilane precursors is deposited onto the integrated circuit substrate to form the Si-containing layer. One of ordinary skill in the art will recognize that at least part of the precursor is deposited” means that some or all of the precursor reacts with or adheres to the integrated circuit substrate. Herein, a reactant may also be used to help in formation of the Si-containing layer.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as an ALD or CVD reaction chamber. The reaction chamber may be maintained at a pressure ranging from about 0.1 Torr to about 10 Torr for all ALD and subatmospheric CVD. Subatmospheric CVD and atmospheric CVD pressures may range up to 760 Torr (atmosphere). In addition, the temperature within the reaction chamber may range from about 350° C. to about 550° C. One of ordinary skill in the art will recognize that the temperature may be optimized through mere experimentation to achieve the desired result.

The temperature of the reactor may be controlled by either controlling the temperature of the substrate holder or controlling the temperature of the reactor wall. Devices used to heat the integrated circuit substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 600° C. When a plasma deposition process is utilized, the deposition temperature may range from approximately 20° C. to approximately 550° C. Alternatively, when a thermal process is performed, the deposition temperature may range from approximately 300° C. to approximately 800° C.

Alternatively, the substrate may be heated to a sufficient temperature to obtain the desired silicon-containing film at a sufficient growth rate and with desired physical state and composition. A non-limiting exemplary temperature range to which the substrate may be heated includes from 150° C. to 600° C. Preferably, the temperature of the substrate remains less than or equal to 500° C.

The reactor contains one or more substrates having a metal interconnection onto which the films will be deposited. A substrate is generally defined as the material on which a process is conducted. The substrates may be any suitable substrate used in semiconductor, photovoltaic, MEMS, flat panel, or LCD-TFT device manufacturing. Examples of suitable substrates include wafers, such as silicon, silica, glass, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers or noble metal layers (e.g. platinum, palladium, rhodium, or gold). The layers may include oxides which are used as dielectric materials in MIM, DRAM, or FeRam technologies (e.g., ZrO₂ based materials, HfO₂ based materials, TiO₂ based materials, rare earth oxide based materials, ternary oxide based materials such as strontium ruthenium oxide [SRO], etc.) or from nitride-based films (e.g., TaN) that are used as an oxygen barrier between copper and the low-k layer. The wafers may include barrier layers, such as manganese, manganese oxide, etc. Plastic layers, such as poly(3,4-ethylenedioxythiophene)poly(styrenesulfonate) [PEDOT:PSS] may also be used. The layers may be planar or patterned. For example, the layer may be a patterned photoresist film made of hydrogenated carbon, for example CHₓ, wherein x is greater than zero.

The disclosed processes may deposit the Si-containing layer directly on the wafer or directly on one or more than one (when patterned layers form the substrate) of the layers on top of the wafer. Furthermore, one of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. In many instances though, the preferred substrate utilized may be selected from hydrogenated carbon, TiN, SRO, Ru, and Si type substrates, such as polysilicon or crystalline silicon substrates. For example, a silicon nitride film may be deposited onto a Si layer. In subsequent processing, alternating silicon oxide and silicon nitride layers may be deposited on the silicon nitride layer forming a stack of multiple SiO₂/SiN layers used in 3D NAND gates.

The disclosed Si-containing film forming compositions may be supplied either in neat form or in a blend with a suitable solvent, such as toluene, ethyl benzene, xylene, mesitylene, decane, dodecane, octane, hexane, pentane, tertiary amines, acetone, tetrahydrofuran, ethanol, ethylmethylketone, 1,4-dioxane, or others. The disclosed Si-containing film forming compositions may be present in varying concentrations in the solvent. For example, the resulting concentration may range from approximately 0.05M to approximately 2M.

The neat or blended Si-containing film forming compositions are delivered into a reactor in vapor form by conventional means, such as tubing and/or flow meters. The composition in vapor form may be produced by vaporizing the neat or blended composition through a conventional vaporization step such as direct vaporization, distillation, by bubbling, or by using a sublimator such as the one disclosed in PCT Publication WO2009/087609 to Xu et al. The neat or blended composition may be fed in liquid state to a vaporizer where it is vaporized before it is introduced into the reactor. Alternatively, the neat or blended composition may be vaporized by passing a carrier gas into a container containing the composition or by bubbling of the carrier gas into the composition. The carrier gas may include, but is not limited to, Ar, He, or N₂, and mixtures thereof. Bubbling with a carrier gas may also remove any dissolved oxygen present in the neat or blended composition. The carrier gas and composition are then introduced into the reactor as a vapor. For example, the flow rate of the disclosed cyclic organoaminosilane precursor may be range from approximately 0.1 to approximately 10 sccm.

The neat or blended Si-containing film forming compositions are delivered into a reactor in vapor form by conventional means, such as tubing and/or flow meters. The composition in vapor form may be produced by vaporizing the neat or blended composition through a conventional vaporization step such as direct vaporization, distillation, by bubbling, or by using a sublimator such as the one disclosed in PCT Publication WO2009/087609 to Xu et al. The neat or blended composition may be fed in liquid state to a vaporizer where it is vaporized before it is introduced into the reactor. Alternatively, the neat or blended composition may be vaporized by passing a carrier gas into a container containing the composition or by bubbling of the carrier gas into the composition. The carrier gas may include, but is not limited to, Ar, He, or N₂, and mixtures thereof. Bubbling with a carrier gas may also remove any dissolved oxygen present in the neat or blended composition. The carrier gas and composition are then introduced into the reactor as a vapor.

If necessary, the container may be heated to a temperature that permits the Si-containing film forming composition to be in its liquid phase and to have a sufficient vapor pressure. The container may be maintained at temperatures in the range of, for example, 0-150° C. Those skilled in the art recognize that the temperature of the container may be adjusted in a known manner to control the amount of Si-containing film forming composition vaporized.

The Si-containing films, such as, SiCN, SiN, or SiC films, formed by the disclosed cyclic organoaminosilane precursors may be deposited with one source process without co-reactants.

The Si-containing films, such as, SiCN, SiN, SiC, SiCOH or SiON films, formed by the disclosed cyclic organoaminosilane precursors may also be deposited with co-reactants.

In addition to the disclosed precursor, a reactant may also be introduced into the reactor. The reactant may be an oxidizing agent, such as one of O₂, O₃, H₂O, H₂O₂; oxygen containing radicals, such as O. or OH., NO, NO₂; carboxylic acids such as formic acid, acetic acid, propionic acid, radical species of NO, NO₂, or the carboxylic acids; para-formaldehyde; and mixtures thereof. Preferably, the oxidizing agent is selected from the group consisting of O₂, O₃, H₂O, H₂O₂, oxygen containing radicals thereof such as O. or OH., and mixtures thereof. Preferably, when an ALD process is performed, the reactant is plasma treated oxygen, ozone, or combinations thereof. When an oxidizing agent is used, the resulting silicon containing film will also contain oxygen.

Alternatively, the reactant may be a reducing agent such as one of H₂, NH₃, (SiH₃)₃N, hydridosilanes (for example, SiH₄, Si₂H₆, Si₃H₈, Si₄H₁₀, Si₅H₁₀, Si₆H₁₂), chlorosilanes and chloropolysilanes (for example, SiHCl₃, SiH₂Cl₂, SIH₃Cl, Si₂Cl₆, Si₂HCl₅, Si₃Cl₈), alkylsilanes (for example, (CH₃)₂SiH₂, (C₂H₅)₂SiH₂, (CH₃)SiH₃, (C₂H₅)SiH₃), hydrazines (for example, N₂H₄, MeHNNH₂, MeHNNHMe), organic amines (for example, N(CH₃)H₂, N(C₂H₅)H₂, N(CH₃)₂H, N(C₂H₅)₂H, N(CH₃)₃, N(C₂H₅)₃, (SiMe₃)₂NH), pyrazoline, pyridine, B-containing molecules (for example, B₂H₆, 9-borabicyclo[3,3,1]none, trimethylboron, triethylboron, borazine), alkyl metals (such as trimethylaluminum, triethylaluminum, dimethylzinc, diethylzinc), radical species thereof, and mixtures thereof. Preferably, the reducing agent is H₂, NH₃, SiH₄, Si₂H₆, Si₃H₈, SiH₂Me₂, SiH₂Et₂, N(SiH₃)₃, hydrogen radicals thereof, or mixtures thereof. Preferably, the reducing agent is SiHCl₃, Si₂Cl₆, Si₂HCl₅, Si₂H₂Cl₄, and cyclo-Si₆H₆Cl₆. When a reducing agent is used, the resulting silicon containing film may be pure Si.

The reactant may be selected from the group consisting of N₂, H₂, NH₃, O₂, O₃, H₂O, monomethyl-hydrazine, H₂O₂, SiH₄, TSA, DCS, TCS, MMS, MCS, SiCl₄, BTBAS, SiH₂(NEt₂)₂, SiH₃(NiPr₂), HCDS or PCDS, trimethylamine or any combination thereof with or without plasma.

The reactant may be treated by plasma, in order to decompose the reactant into its radical form. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

The disclosed Si-containing film forming composition may also be used with a halosilane or polyhalodisilane, such as hexachlorodisilane, pentachlorodisilane, or tetrachlorodisilane, and one or more reactants to form Si, SiCN, or SiCOH films. PCT Publication Number WO2011/123792 discloses a SiN layer, and the entire contents of which are incorporated herein in their entireties.

When the desired Si-containing film also contains another element, such as, for example and without limitation, Ta, Hf, Nb, Mg, Al, Sr, Y, Ba, Ca, As, Sb, Bi, Sn, Pb, Co, lanthanides (such as Er), or combinations thereof, the reactants may include another precursor which is selected from, but not limited to, alkyls, such as Ln(RCp)₃ or Co(RCp)₂, amines, such as Nb(Cp)(NtBu)(NMe₂)₃ or any combination thereof.

The Si-containing film forming composition and one or more reactants may be introduced into the reaction chamber simultaneously (e.g., CVD), sequentially (e.g., ALD), or in other combinations. For example, the Si-containing film forming composition may be introduced in one pulse and two additional reactants may be introduced together in a separate pulse (e.g., modified ALD). Alternatively, the reaction chamber may already contain the reactant prior to introduction of the Si-containing film forming composition. The reactant may be passed through a plasma system localized or remotely from the reaction chamber, and decomposed to radicals. Alternatively, the Si-containing film forming composition may be introduced to the reaction chamber continuously while other reactants are introduced by pulse (e.g., pulsed-CVD). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the Si-containing film forming composition and one or more reactants may be simultaneously sprayed from a shower head under which a susceptor holding several wafers is spun (e.g., spatial ALD).

In one non-limiting exemplary ALD type process, the vapor phase of a Si-containing film forming composition is introduced into the reaction chamber, where at least part of the cyclic organoaminosilane precursor reacts with a suitable substrate, such as Si, SiO₂, Al₂O₃, etc., to form an adsorbed silane layer. Excess composition may then be removed from the reaction chamber by purging and/or evacuating the reaction chamber. An oxygen source is introduced into the reaction chamber where it reacts with the absorbed silane layer in a self-limiting manner. Any excess oxygen source is removed from the reaction chamber by purging and/or evacuating the reaction chamber. If the desired film is a silicon oxide film, this two-step process may provide the desired film thickness or may be repeated until a film having the necessary thickness has been obtained.

Alternatively, if the desired film contains a second element (i.e., SiMOₓ, wherein x may be 4 and M is Ta, Hf, Nb, Mg, Al, Sr, Y, Ba, Ca, As, Sb, Bi, Sn, Pb, Co, lanthanides (such as Er), or combinations thereof), the two-step process above may be followed by introduction of a vapor of a second precursor into the reaction chamber. The second precursor will be selected based on the nature of the oxide film being deposited. After introduction into the reaction chamber, the second precursor is contacted with the substrate. Any excess second precursor is removed from the reaction chamber by purging and/or evacuating the reaction chamber. Once again, an oxygen source may be introduced into the reaction chamber to react with the second precursor. Excess oxygen source is removed from the reaction chamber by purging and/or evacuating the reaction chamber. If a desired film thickness has been achieved, the process may be terminated. However, if a thicker film is desired, the entire four-step process may be repeated. By alternating the provision of the cyclic organoaminosilane precursor, second precursor, and oxygen source, a film of desired composition and thickness can be deposited.

Additionally, by varying the number of pulses, films having a desired stoichiometric M:Si ratio may be obtained. For example, a SiMO₂ film may be obtained by having one pulse of the Si-containing film forming composition and one pulses of the second precursor, with each pulse being followed by pulses of the oxygen source. However, one of ordinary skill in the art will recognize that the number of pulses required to obtain the desired film may not be identical to the stoichiometric ratio of the resulting film.

In another alternative, dense SiCN films may be deposited using an ALD method with hexachlorodisilane (HCDS) or pentachlorodisilane (PCDS), or diiodosilane, the disclosed Si-containing film forming composition, and an ammonia reactant. The reaction chamber may be controlled at 5 Torr, 550° C., with a 55 sccm continuous flow of Ar. An approximately 10 second long pulse of the Si-containing film forming composition at a flow rate of approximately 1 sccm is introduced into the reaction chamber. Any excess Si-containing film forming composition is purged from the reaction chamber with an approximately 55 sccm flow of Ar for approximately 30 seconds. An approximately 10 second pulse of HCDS at a flow rate of approximately 1 sccm is introduced into the reaction chamber. Any excess HCDS is purged from the reaction chamber with an approximately 55 sccm flow of Ar for approximately 30 seconds. An approximately 10 second long pulse of NH₃ at a flow rate of approximately 50 sccm is introduced into the reaction chamber. Any excess NH₃ is purged from the reaction chamber with an approximately 55 sccm flow of Ar for approximately 10 seconds. These 6 steps are repeated until the deposited layer achieves a suitable thickness. One of ordinary skill in the art will recognize that the introductory pulses may be simultaneous when using a spatial ALD device. As described in PCT Pub No WO2011/123792, the order of the introduction of the precursors may be varied and the deposition may be performed with or without the NH₃ reactant in order to tune the amounts of carbon and nitrogen in the SiCN film.

In yet another alternative, a Si-containing film may be deposited by the flowable PECVD method disclosed in U.S. Patent Application Publication No. US2014/0051264 A1 using the disclosed compositions and a radical nitrogen- or oxygen-containing reactant. The radical nitrogen- or oxygen-containing reactant, such as NH₃ or H₂O respectively, is generated in a remote plasma system. The radical reactant and the vapor phase of the disclosed compositions are introduced into the reaction chamber where they react and deposit the initially flowable film on the substrate. Applicants believe that the nitrogen atoms of the amino groups in the disclosed precursors help to further improve the flowability of the deposited film, resulting in films having less voids or pores (i.e., dense films).

The Si-containing films resulting from the processes discussed above may include SiCN, SiN, SiC, SiCOH or SiON. One of ordinary skill in the art will recognize that by judicial selection of the appropriate Si-containing film forming composition and reactants, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the Si-containing film may be exposed to a temperature ranging from approximately 200° C. and approximately 1000° C. for a time ranging from approximately 0.1 second to approximately 7200 seconds under an inert atmosphere, a H-containing atmosphere, a Si-containing atmosphere, an O-containing atmosphere, or combinations thereof. Most preferably, the temperature is 600° C. for less than 3600 seconds under an H-containing atmosphere. The resulting film may contain fewer impurities and therefore may have improved performance characteristics. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Si-containing film.

### EXAMPLES

The following non-limiting examples are provided to further illustrate embodiments of the invention. However, the examples are not intended to be all inclusive and are not intended to limit the scope of the inventions described herein.

### Example 1

### Synthesis of Bis(Pyrrolidino)Silacyclopentane

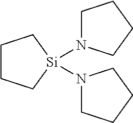 [SMILES: C1CCN([Si]2(N3CCCC3)CCCC2)C1]

Bis(pyrrolidino)silacyclopentane was synthesized with the following route.

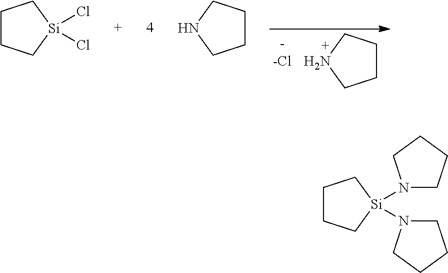

Under an atmosphere of pure N₂, pyrrolidine (50 mL, 0.600 mol) is added dropwise to a 0° C. solution of 1,1-dichlorosilacyclopentane (21.7 g, 0.140 mol) in pentane (400 mL) with vigorous stirring. An immediate white precipitate is observed. After the addition is complete, the suspension is warmed to ambient temperature while stirring overnight. The following day, stirring is stopped to allow precipitate to settle and supernatent solution filtered over a medium pore glass frit with a bed of treated diatomaceous earth. The precipitate is then extracted with 1×70 mL pentane and the extracts combined and filtered with above to yield a colorless solution.

Light volatiles are distilled off at 30-40° C. and atmospheric pressure. A fresh receiving flask is added and desired product is distilled at 55-60° C./50 mTorr as a colorless, free flowing liquid (21.8 g, 69%). ¹H NMR (C₆D₆, 400 MHz) δ(ppm)=2.97 (t, 8H, N—CH₂), 1.67-1.62 (m, 4H, Si—CH₂—CH₂), 1.62-1.59 (m, 8H, N—CH₂—CH₂), 0.65 (t, 4H, Si—CH₂).

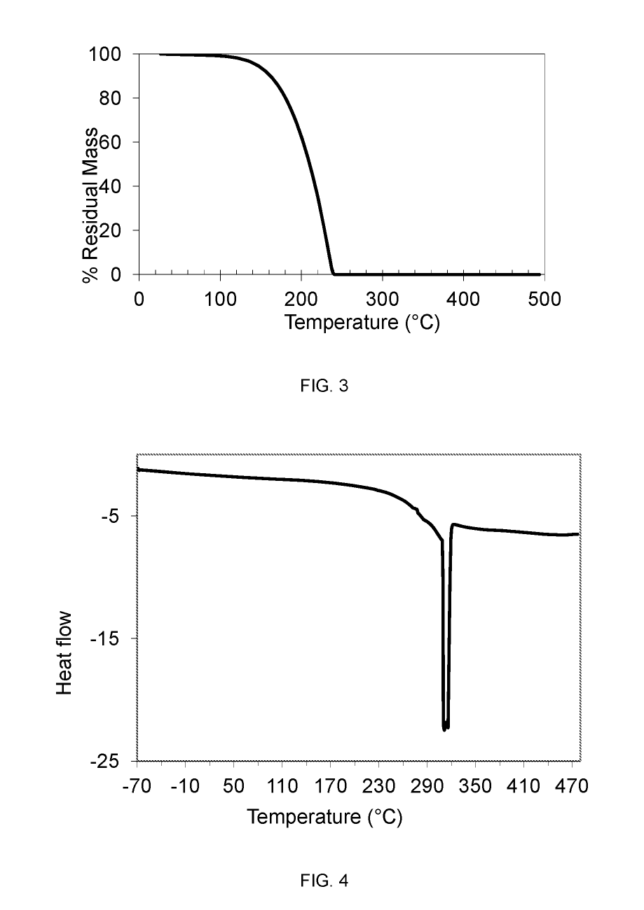

FIG. 3 is a Thermogravimetric Analysis (TGA) graph demonstrating the percentage of mass loss with increasing temperature of bis(pyrrolidino)silacyclopentane. As shown, bis(pyrrolidino)silacyclopentane has good volatility and low residue. FIG. 4 is a graph of the differential scanning calorimetry (DSC) measurement for bis(pyrrolidino)silacyclopentane. As shown, a strong endotherm peak appears at 311-316° C.

The properties of bis(pyrrolidino)silacyclopentane are as follows.

Vapor pressure=1 Torr @ 77° C.

ΔHᵥₐₚ=14.4 kcal/mol.

Isolated Yield=21.7 g (69% unoptimized).

TGA residue (oc)=<1%.

Density=0.976 g/mL.

Viscosity=3.02 cSt.

No MP observed to −70° C.

Appearance: colorless liquid.

### Example 2

### Synthesis of 1-(pyrrolidino)silacyclopentane

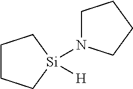

1-(pyrrolidino)silacyclopentane was synthesized with the following route.

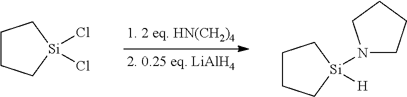 [SMILES: Cl[Si]1(Cl)CCCC1 ; C1CCN([SiH]2CCCC2)C1]

Under an atmosphere of pure N₂, a solution of pyrrolidine (43 mL, 0.515 mol) in pentane (50 mL) is added dropwise to a −40° C. solution of 1,1-dichlorosilacyclopentane (40.1 g, 0.259 mol) in pentane (400 mL). An immediate white precipitate is observed. After the addition is complete, the suspension is warmed to ambient temperature while stirring overnight. The following day, stirring is stopped to allow precipitate to settle and supernatent solution filtered over a medium pore glass frit with a bed of treated diatomaceous earth. The precipitate is then extracted with 1×70 mL pentane and the extracts combined and filtered with above to yield a hazy, colorless solution.

The solvent volume is reduced by 50% under reduced pressure and the solution cooled to −40° C. after which is added dropwise a 1.0M solution of lithium aluminum hydride in diethyl ether (65 mL, 0.065 mol). After the addition is complete, the suspension is warmed to ambient temperature while stirring overnight, during which a fluffy white precipitate slowly forms. The following day, stirring is stopped to allow precipitate to settle and supernatent solution filtered over a medium pore glass frit with a bed of treated diatomaceous earth. The precipitate was then extracted with 1×70 mL pentane and the extracts combined and filtered with above to yield a colorless solution.

Solvents are distilled off at 30-40° C. and atmospheric pressure using a Vigreux column. A fresh receiving flask is added and desired product is distilled at 25-30° C./140 mTorr as a colorless, free flowing liquid (7.6 g, 19%). ¹H NMR (C₆D₆, 400 MHz) δ(ppm)=4.93 (m, 1H, Si—H), 2.88 (t, 4H, N—CH₂), 1.66-1.55 (m, 4H, Si—CH₂—CH₂), 1.55-1.51 (m, 4H, N—CH₂—CH₂), 0.70 (t, 4H, Si—CH₂).

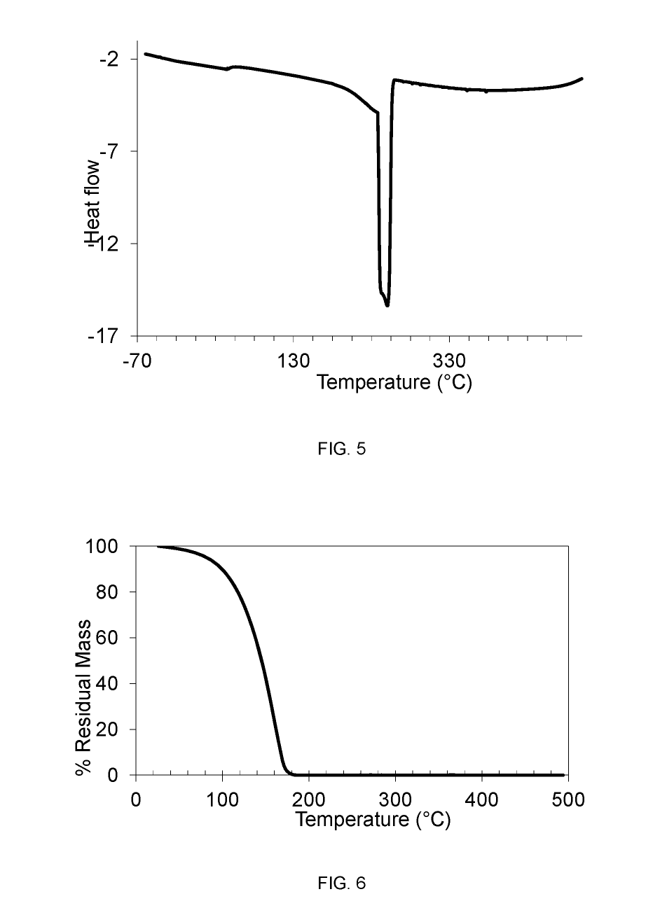

FIG. 5 is a TGA graph demonstrating the percentage of weight loss with increasing temperature of 1-(pyrrolidino)silacyclopentane. As shown, 1-(pyrrolidino)silacyclopentane has good volatility and low residue. FIG. 6 is a graph of a DSC measurement for 1-(pyrrolidino)silacyclopentane. As shown, a strong endotherm peak appears at 251° C.

The properties of 1-(pyrrolidino)silacyclopentane are as follows.

Vapor pressure=1 Torr @ 22° C.

ΔHᵥₐₚ=9.4 kcal/mol.

Isolated Yield=11.3 g (19% unoptimized).

TGA residue (oc)=<1%.

Density=0.91 g/mL.

Viscosity=1.7 cSt.

No MP observed to −70° C.

Appearance: colorless liquid.

### Example 3

### Bis(Pyrrolidino)Silacyclopentane Deposition Using PECVD

Bis(pyrrolidino)silacyclopentane precursor was used to deposit a SiCN film using PECVD. The typical PECVD conditions used are: the plasma power set to 10 W, reactor pressure set at 5-8 torr and the wafer temperature measured at 350° C. The films were deposited on pure silicon wafers. The flow rate of bis(pyrrolidino)silacyclopentane precursor carried by He was 50 sccm at 150 torr. The flow rate of He was 160 sccm.

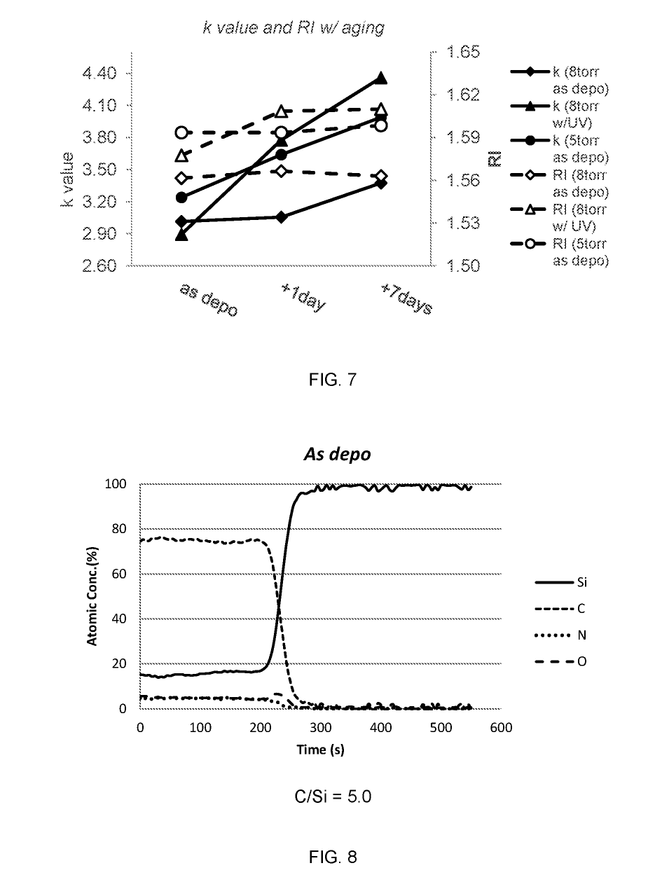

FIG. 7 is a graph of the k value and RI value as a function of the post deposition aging time in days for the film deposited using bis(pyrrolidino)silacyclopentane precursor by PECVD at 5 torr and 8 torr, respectively. As shown, k value of the film deposited by bis(pyrrolidino)silacyclopentane is less than 3.30, remains unchanged in one day and then slightly increases in 7 days at 8 torr. Whereas, the k value of the 8 torr film increases with aging after the film is UV cured. The k value for the 5 torr deposited, uncured film also increases with aging. The RI value is between 1.56 and 1.60, and remains unchanged (within error limits) with aging for either 5 or 8 torr deposition pressure, or for 8 torr pressure followed by a UV curing treatment.

FIG. 8 is a graph of XPS analysis data for the film deposited with bis(pyrrolidino)silacyclopentane by PECVD without UV curing. As illustrated, the ratio of C/Si in the film is 5. Nitrogen content in the film is approximately 5%. Oxygen diffusion into the film is approximately 5%.

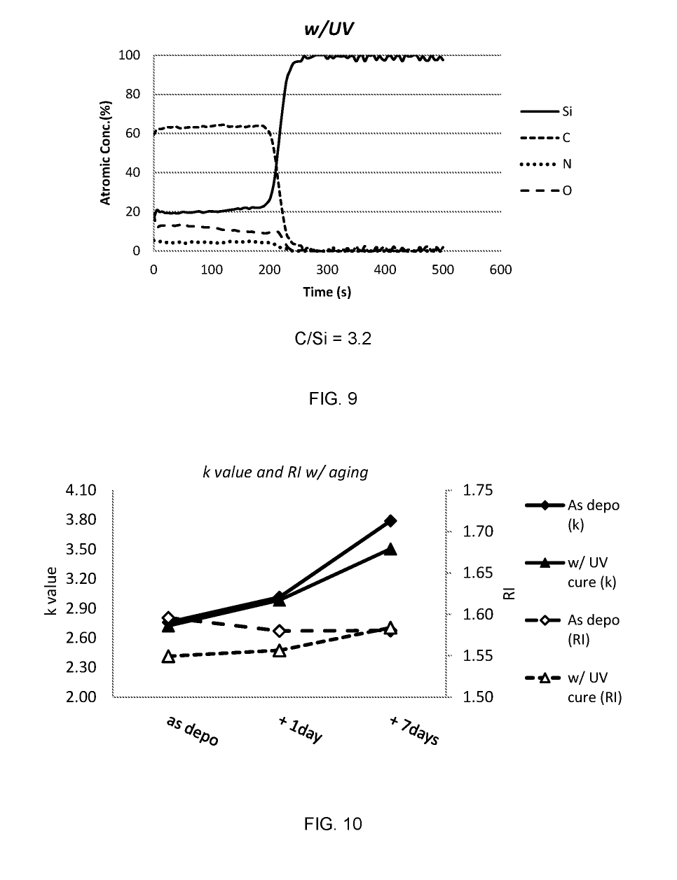

FIG. 9 is a graph of XPS analysis data for the film deposited with bis(pyrrolidino)silacyclopentane by PECVD with UV curing. As illustrated, the ratio of C/Si in the UV cured film is 3.2. The carbon content in the UV cured film decreased comparing to the film without UV curing. The nitrogen content in the UV cured film is approximately 5%. Significant oxygen diffusion into the UV cured film was also observed (approximately 15%).

Young's modulus result for the film without UV curing is 8.5 GPa, whereas Young's Modulus result for the film with UV curing is 12.4 GPa. Young's modulus result for the film without UV curing is lower than that for the film with UV curing, which may result from the high carbon content in the film without UV curing.

These initial research results may suggest that the deposited films derived from bis(pyrrolidino)silacyclopentane precursor may not be suitable for use as a dielectric barrier layer. However, as Si containing films were successfully deposited, further optimization of the deposition parameters may provide improved results. Additionally the deposited films may be suitable for manufacturing semiconductor and electronics devices, such as, integrated circuit, interconnects, spacers, photovoltaics, displays, lighting LEDs, MEMS, image sensors or aeronautics. For example, these films may be suitable for a sacrificial silicon nitride layer in microfabrication processes.

### Example 4

### Diisopropylaminosilacylopentane Deposition Using PECVD

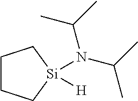

Diisopropylaminosilacylopentane was prepared using the method described above and PEALD tests performed usingthis product. The typical PECVD conditions used: plasma power set to 10 W, reactor pressure was set at 8 torr, the wafer temperature was measured at 350° C. and the deposition was performed on pure silicon wafers. The flow rate of diisopropylaminosilacylopentane carried by He was 50 sccm at 150 torr while the flow rate of He was set to 160 sccm.

FIG. 10 is a graph of k value and RI value as a function of the post deposition storage time in days for the film deposited using diisopropylaminosilacylopentane by PECVD at 8 torr. As illustrated, the k value of the film deposited by diisopropylaminosilacylopentane is less than 2.80, remains approximately unchanged in one day and then slightly increases after 7 days with and without UV cured, respectively. The RI values are low around 1.58 for both the films with and without UV cured after 7 days. Comparing to the RI values at the time when the films were formed, the RI value for the film that has been UV cured increases from 1.55 to 1.58 and the RI value for the film without UV curing treatment decreases from 1.60 to 1.58.

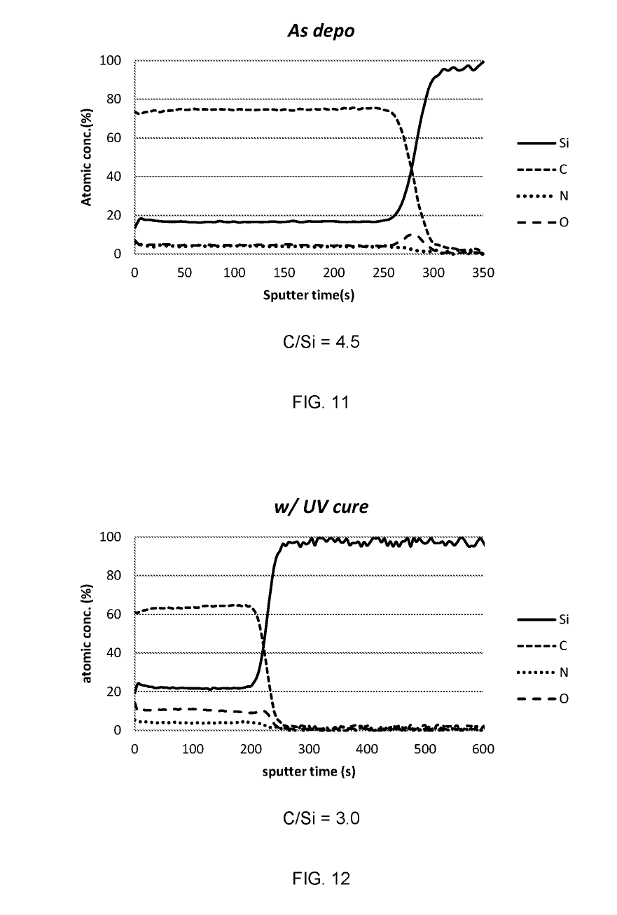

FIG. 11 is a graph of XPS analysis data for the film deposited using diisopropylaminosilacylopentane by PECVD without UV curing. As illustrated, the ratio of C/Si in the film is 4.5. Nitrogen content in the film is approximately 5%. Oxygen diffusion into the film is approximately 5%.

FIG. 12 is a graph of XPS analysis data for the film deposited using diisopropylaminosilacylopentane by PECVD with UV curing. As illustrated, the ratio of C/Si in the UV cured film is 3. The carbon content in the UV cured film is reduced comparing to the film without UV curing. The nitrogen content in the UV cured film is approximately 5%. Significant oxygen diffusion into the UV cured film was also observed (approximately 12%).

The Young's modulus result for the film without UV curing is 9 GPa, whereas Young's Modulus result for the film with UV curing is 8.5 GPa. Young's modulus results for the films with and without UV curing are all weak, which may result from carbon disorder (amorphous carbon in the films) and lack of carbon backbone in both films.

These initial research results may suggest that the deposited films derived from diisopropylaminosilacylopentane precursor may not be suitable for use as a dielectric barrier layer. However, as Si containing films were successfully deposited, further optimization of the deposition parameters may provide improved results. Additionally the deposited films may be suitable for manufacturing semiconductor and electronics devices, such as, integrated circuit, interconnects, spacers, photovoltaics, displays, lighting LEDs, MEMS, image sensors or aeronautics. For example, these films may be suitable for a sacrificial silicon nitride layer in microfabrication processes.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A method for forming a silicon-containing layer on a substrate, the method comprising the steps of:
introducing into a reactor containing a substrate a vapor including a Si-containing film forming composition having a cyclic organoaminosilane precursor having the formula: 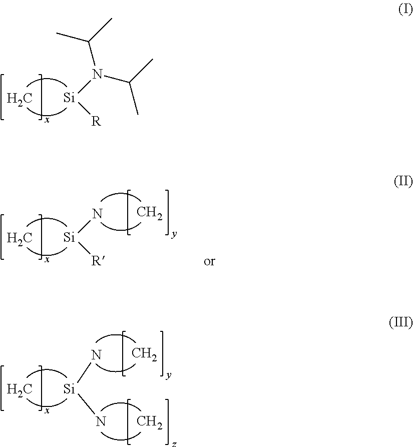
wherein R is NH₂; R′ is H or NH₂; x, y or z=2 to 5; provided that x≠4 in the formula (III); and
depositing at least part of the cyclic organoaminosilane precursor onto the substrate to form the silicon-containing layer on the substrate using a vapor deposition process.

2. The method of claim 1, wherein the cyclic organoaminosilane precursor is selected from the group consisting of 1-(diisopropylamino)-1-amino-silacyclopentane, 1-(pyrrolidino)silacyclobutane, 1-(pyrrolidino)silacyclopentane, 1-(pyrrolidino)silacyclohexane, 1-(piperidino)silacyclobutane, 1-(piperidino)silacyclopentane, 1-(piperidino)silacyclohexane, 1-(pyrrolidino)-1-amino-silacyclobutane, 1-(pyrrolidino)-1-amino-silacyclopentane, 1-(pyrrolidino)-1-amino-silacyclohexane, 1-(piperidino)-1-amino-silacyclobutane, 1-(piperidino)-1-amino-silacyclopentane, 1-(piperidino)-1-amino-silacyclohexane, bis(pyrrolidino)silacyclopentane, bis(pyrrolidino)silacyclohexane, bis(piperidino)silacyclobutane, bis(piperidino)silacyclopentane, bis(piperidino)silacyclohexane, and mixtures thereof.

3. The method of claim 1, wherein the cyclic organoaminosilane precursor is bis(pyrrolidino)silacyclopentane.

4. The method of claim 1, wherein the cyclic organoaminosilane precursor is 1-(pyrrolidino)silacyclopentane.

5. The method of claim 1, further comprising the step of delivering into the reactor a reactant.

6. The method of claim 5, wherein the reactant is selected from the group consisting of N₂, H₂, NH₃, O₂, O₃, H₂O, monomethyl-hydrazine, H₂O₂, SiH₄, TSA, DCS, TCS, MMS, MCS, SiCl₄, BTBAS, SiH₂(NEt₂)₂, SiH₃(NiPr₂), HCDS, trimethylamine or any combination thereof with or without plasma.

7. The method of claim 1, wherein the silicon-containing layer formed by the cyclic organoaminosilane precursor is deposited with one source process without co-reactants.

8. The method of claim 1, wherein the silicon-containing layer is a SiN, SiCN, SiON, SiCOH or SiC film.

9. The method of claim 1, wherein the vapor deposition process is selected from CVD, ALD, PECVD, PEALD, pulsed-CVD, SACVD, LPCVD, APCVD or a combination thereof.

10. The method of claim 1, wherein the vapor deposition process is a plasma enhanced chemical deposition process (PECVD).
